(19) United States
(12) Patent Application Publication
(10) Pub. No.: US 2005/0092595 A1
(43) Pub. Date: May 5, 2005

(54) Ion gauge condition detector and switching circuit

(75) Inventors: Karl Peterson, Mechanicsville, VA (US); Michael Wright, Richmond, VA (US); Frederico Garza, Richmond, VA (US)

Correspondence Address: STAAS & HALSEY LLP, SUITE 700, 1201 NEW YORK AVENUE, N.W., WASHINGTON, DC, 20005, US

(73) Assignee: Infineon Technologies Richmond, LP, Sandston, VA (US)

(21) Appl. No.: 10/697,656

(22) Filed: Oct. 31, 2003

(51) Int. Cl. C23C 14/00; G01N 27/26

(52) U.S. Cl. 204/192.11; 204/416

(57) ABSTRACT

A device to implant impurities into a semiconductor wafer had a beam gun to shoot ions at a semiconductor wafer, a pair of ion gauges, and ion gauge controller to supply power to, and obtain information corresponding to a number of ions from, one of the ion gauges. The gauge controller has a parameter output, a control output and a pair of control inputs respectively associated with the pair of ion gauges, such that when a control signal is supplied to one of the control inputs, the ion gauge controller supplies power to, and obtains information corresponding to a number of ions from, the respectively associated ion gauge. The control output produces the control signal when either of the ion gauges is activated. The parameter output selectively produces a parameter signal based on a recipe selection. A first delay circuit connects the control output to one of the control inputs, after a delay, when the parameter output is on. A second delay circuit connects the control outputs to the other of the control inputs, after a delay, when the parameter output is off.

### BACKGROUND OF THE INVENTION

Impurities are implanted into semiconductor devices for a variety of reasons, including introducing electrons and holes into the semiconductor substrate in order to locally change the conductive properties of the substrate. For example, silicon has four electrons in the outer ring. Phosphorus has five electrons in its outer ring, one more than silicon. Boron has three electrons in its outer ring, one fewer electron than silicon. Boron can be used to introduce holes into the substrate. Phosphorous can be used to introduce electrons into the substrate.

To enable implantation, the impurities are implanted as ions having one fewer electron than the neutral species. During the implantation process, the electron deficit can be used to determine how much impurity has been implanted. Specifically, it is not possible to accurately count the number of ions (or atoms) leaving the ion gun. Therefore, a predetermined portion of the ions is directed to an ion counter instead of the semiconductor wafer(s). The ion counter may be embodied has a disk faraday. When an ion strikes the disk faraday, an electron is pulled to the disk faraday in order to neutralize the ion. The number of electrons pulled to the disk faraday is counted using a current meter. It is presumed that the number of ions striking in the disk faraday is proportional to the number of ions striking and entering the semiconductor wafer.

The current (electrons per second) represents the rate at which impurities are introduced into the wafer. If the implanter detects that one area of the wafer is receiving impurities at a slower rate than other areas of the wafer, then the implanter spends more time implanting on the deficient area. In this manner, the implanter can work to achieve uniform total dosing across the surface of the wafer.

When the ions hit the semiconductor wafer, they may destroy a portion of a resist layer formed on the wafer. This process releases an outgas into the implant chamber, which would otherwise kept at a very low pressure. Electrons from the outgas can neutralize a portion of the ions, before the ions reach the disk faraday or the semiconductor wafer. Although the ions are neutralized by the resist outgas (rather than being neutralized at the disk faraday or within the semiconductor wafer), the neutral species is still implanted and still causes the desired change to the substrate. However, because the neutral species contains the correct number of electrons, there is not disk faraday current flow for neutralization. Therefore, the neutral species are not counted.

In order to count the impurities implanted as atoms, rather than ions, a pressure sensor is used. As the pressure increases from resist outgassing, it is presumed that a larger percentage of the impurities are introduced into the wafer as atoms rather than ions.

The following equation represents how pressure is taken into consideration to determine the number of ions implanted.
I_{DISK}=I_{DOSE}·e^{-KP}

In the above equation, I_{DISK} is the current flowing to the disk faraday. This current is proportional to the number of ions implanted. I_{DISK} is the rate at which impurities (ions+atoms) are implanted. P is the pressure as sensed by the ion gauge/pressure sensor within the device. K is a factor determined by the engineer and input into the implanter. K represents how a pressure change is presumed to effect ion neutralization.

Instead of, or in addition to, the K-factor shown above, a pressure compensation factor P-COMP can be used. The mathematical relationship between K and P-COMP is as follows:

$$P - COMP = 100 ( {ⅇ}^{K / 10000} - 1 ) or$$

$$K = ln ( 1 + \frac{P - COMP}{100} ) ( 10000 )$$

Because K and P-COMP are interchangeable through simple math, the term “pressure compensation factor” is used hereinafter to represent both K and P-COMP with the understanding that the two parameters are interchangeable through the above mathematical relationships.

The process chamber is kept at a very low pressure. By detecting pressure increases, the ion gauge is able to calculate the number of ions within the chamber. The chamber is held at a near-vacuum through cryogenic pumps. The conventional ion gauge is located outside of the process chamber, near a cryogenic pump. However, this location reduces the accuracy of the pressure reading for two reasons. First, resist outgassing causes dramatic increase of pressure near the wafer. This high pressure is localized and drops with distance. At the location of the ion gauge, the pressure has dropped significantly, causing an artificially low pressure reading. Second, the ion gauge is in close proximity to the cryogenic pump, which reduces chamber pressure. The cryogenic pump also reduces the pressure reading of the ion gauge.

With high energy implants, the pressure increase is sufficiently high that the implanter can accommodate the pressure inaccuracies. At the outside chamber location, the ion gauge can accurately sense pressure changes produced by implanting high energy impurities, such as arsenic. That is, the high energy of arsenic causes a lot of resist outgassing, and hence a large pressure increases. By positioning the pressure sensor away from the chamber, near the cryogenic pump, pressure changes are reduced to a range where the ion gauge operates efficiently.

The inventors are now proposing to install a new ion gauge to an ion implanter such as the Axcelis GSD platform implanters. The new ion gauge may be installed in the process chamber. The new ion gauge may be advantageous for implants such as nitrogen, which produce similar pressure responses, such as significantly below 1×10⁻⁴. However, for more conventional implants, the pressure is too high to be accurately sensed by the new ion gauge. For example, conventional implants such as arsenic produce pressures greater than 1.0×10₄ Torr. A single ion gauge cannot effectively be used for both implants. For this reason, it is desirable for the implanter to be equipped with both a conventional ion gauge and the new, inside-process-chamber ion gauge. However, many conventional ion implanters have only a single ion gauge controller. Additionally, it is desirable that the implanter should be able to automatically switch between the ion gauges depending on the implanted recipe. Further, it is desirable that the automatic switching be done without excessive expense or time consuming hardware.

### SUMMARY OF THE INVENTION

To possibly address these and other concerns, the inventors propose tapping into an electrical output that is controlled by recipe specific parameter. This may enable automatic selection between one of two ion gauges on an implanter that has only one ion gauge controller. According to one embodiment, an input from a beam line gas switch or other unused recipe parameter, determines which ion gauge, the process chamber ion gauge or the factory installed ion gauge is to be used. In preparing the implant process recipe, if the beam line gas is selected to be on, for example, the process chamber ion gauge is used for pressure monitoring. If the recipe is programmed so as not to employ beam line gas, then the conventional pressure sensor is used. A gauge conditioning circuit and gauge condition indicator may enable the implant operator to determine which gauge is being used. The gauge condition indicator may be an LED installed on the front of the implanter, near a user interface screen.

The inventors propose a device to implant impurities into a semiconductor wafer. This device has a beam gun to shoot ions at a semiconductor wafer, a pair of ion gauges, an ion gauge controller to supply power to, and obtain information corresponding to a number of ions from, one of the ion gauges. The gauge controller has a parameter output, a control output and a pair of control inputs respectively associated with the pair of ion gauges, such that when a control signal is supplied to one of the control inputs, the ion gauge controller supplies power to, and obtains information corresponding to a number of ions from, the respectively associated ion gauge. The control output produces the control signal when either of the ion gauges is activated. The parameter output selectively produces a parameter signal based on a recipe selection. A first delay circuit connects the control output to one of the control inputs, after a delay, when the parameter output is on. A second delay circuit connects the control output to the other of the control inputs, after a delay, when the parameter output is off.

The control output may be a beam line gas output. The beam line gas output may be connected to a beam line gas device, which is capped.

A pair of relay circuits may be provided, each connected between one of the delay circuits and one of the control inputs to connect the control output to one of the control inputs when a voltage signal is received from the delay circuit connected thereto. A hex buffer may be connected between each delay circuit and the corresponding relay circuit.

The device may also have an inverter is positioned between the parameter output and one of the delay circuits such that one of the delay circuits is turned on when the other delay circuit is turned off. In this case, each delay circuit has a discharge transistor and a resistor-capacitor combination. The resistor-capacitor combination produces a constant time delay when the delay circuit is turned on. The discharge transistor discharges the resistor-capacitor combination when the delay circuit is turned off.

The inventors also propose a device to implant impurities into a semiconductor wafer, which has a base unit having a plurality of interfaces comprising an input to receive an implant recipe an unused output to control a recipe parameter not used in both a high energy implant and a low energy implant. This device also has an ion gauge controller provided in the base unit, a beam gun to shoot ions at a semiconductor wafer, first and second ion gauges, and

a switch to selectively connect either the first or second ion gauge to the ion gauge controller. The switch is activated by a trigger connected to the unused interface of the base unit.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1A is a schematic side view of an ion implanter;

FIG. 1B is a schematic side view of the pressure sensor controller;

FIG. 2A is a schematic side view of a disk faraday used to determine beam current, which is in turn used to count the number of implanted ions;

FIG. 2B is a top view of a disk holding a plurality of wafers for implantation;

FIG. 2C is an enlarged top view of the disk shown in FIG. 2B;

FIG. 3 is a side view of the disk faraday shown in FIG. 2A and the disk shown in FIGS. 2B and 2C;

FIG. 4 is a schematic representation of the time spent on the wafer during the beam travel path;.

FIG. 5 shows the correlation between the time the beam spends on the wafer at various disk positions, the amount of outgassing, the number of neutral species implanted and the amount of overdose if the neutral species are ignored in the calculations;

FIG. 6 is a plot of mean sheet resistance versus P-COMP values for a conventional method of determining a P-COMP value;

FIG. 7 shows an X-Y plot of the uncompensated beam current I_{DISK} as a function of disk radius;

FIG. 8A is a plot of vertical disk speed versus disk position;

FIG. 8B is a plot of vertical disk speed versus disk position when outgassing causes a drop in beam current;

FIG. 9 is a sheet resistance map for an a non-uniformly dosed wafer;

FIGS. 10A and 10B are plots of beam current and pressure versus disk position for a higher energy implant;

FIGS. 11 A and 11B are plots of uncorrected beam current and pressure versus disk position for a lower power implants such as nitrogen;

FIG. 11C is a plot of pressure versus disk radius using an ion gauge located within the process chamber; and

FIG. 12 is a schematic view of a switching circuit to switch between the first and second ion gauges (pressure sensors) shown in FIG. 1A.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

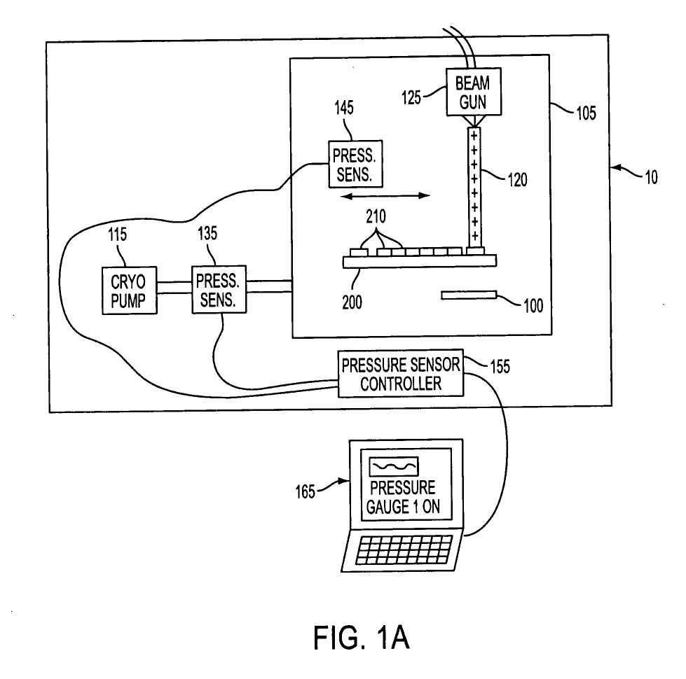

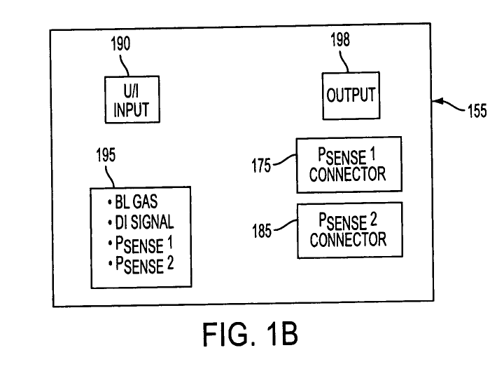

FIG. 1A is a schematic side view of an ion implanter 10. The implanter has a chamber 105, which is kept at a very low pressure by cryo pumps, one of which is represented by reference numeral 115. Within the chamber 105, a beam gun 125 produces an ion beam 120 which is focused on wafers 210. The wafers 210 are placed around a disk 200. A faraday 100 is provided under the disk 200 to sense beam current. A first pressure sensor 135 is provided outside of the chamber 105 in the vicinity of the cryo pump 115. This location corresponds with a conventional location and is useful for implanting ions that produce a large pressure response during resist outgassing. A second pressure sensor 145 is provided within the chamber 105. The second pressure sensor (an ion gauge) 145 is useful for the implanting impurities that exhibit a smaller pressure response with resist outgassing. Both the first and second pressure sensors 135, 145 are connected to a pressure sensor controller 155. The pressure sensor controller 155 is in turn connected to a user interface 165. On the user interface 165, the pressure from one of the pressure sensors 135, 145 is displayed together with an indication of which pressure sensor or gauge is being used.

FIG. 1B is a schematic side view of the pressure sensor controller 155. Connectors 175, 185 are provided respectively for the first and second pressure sensors 135, 145. Through these connectors 175, 185, the pressure sensors 135, 145 communicate with the pressure sensor controller 155. A user interface input 190 receives information regarding the recipe from the user interface 165. A connector 195 allows various signals within the pressure sensor controller 155 to be manipulated. An output 198 supplies information regarding the detected pressure (or detected number of ions) and information regarding which pressure sensor is active. The information regarding the detected pressure may be provided as an analog output. The information from the output 198 may be provided to the user interface 165 or to a separate display on the implanter 10.

In FIG. 1A an additional ion gauge 145 is added to the implanter 10. This ion gauge 145 is located to close to the wafer 210 such that it can more accurately determine pressure changes. In the process chamber 105, the ion gauge 145 is closer to where resist outgassing, pressure increases and beam neutralization occurs. This placement works well for recipes having a high ratio of beam neutralization to pressure increase.

In order to place the ion gauge 145 within the process chamber 105, a hole is drilled in the process chamber 105. The ion gauge mounting hardware is installed. The ion gauge 145 is installed and connected to the ion gauge controller 155.

Under resist outgassing conditions, the beam current drops due to recombination. Recombination is when an ion is combined with an electron and becomes a neutral atom. The neutral atom is still implanted into the wafer but not counted by the disk faraday of the implanter. Therefore, for every neutralized ion at a specific wafer area, the implanter focuses the beam on the wafer for an additional time long enough to implant one additional ion. This causes an overdose of one ion. The amount of resist exposed to the beam is greatest at the vertical center of the wafer. If pressure compensation is not used, the vertical center of the wafer is overdosed relative to the top and bottom areas of the wafer.

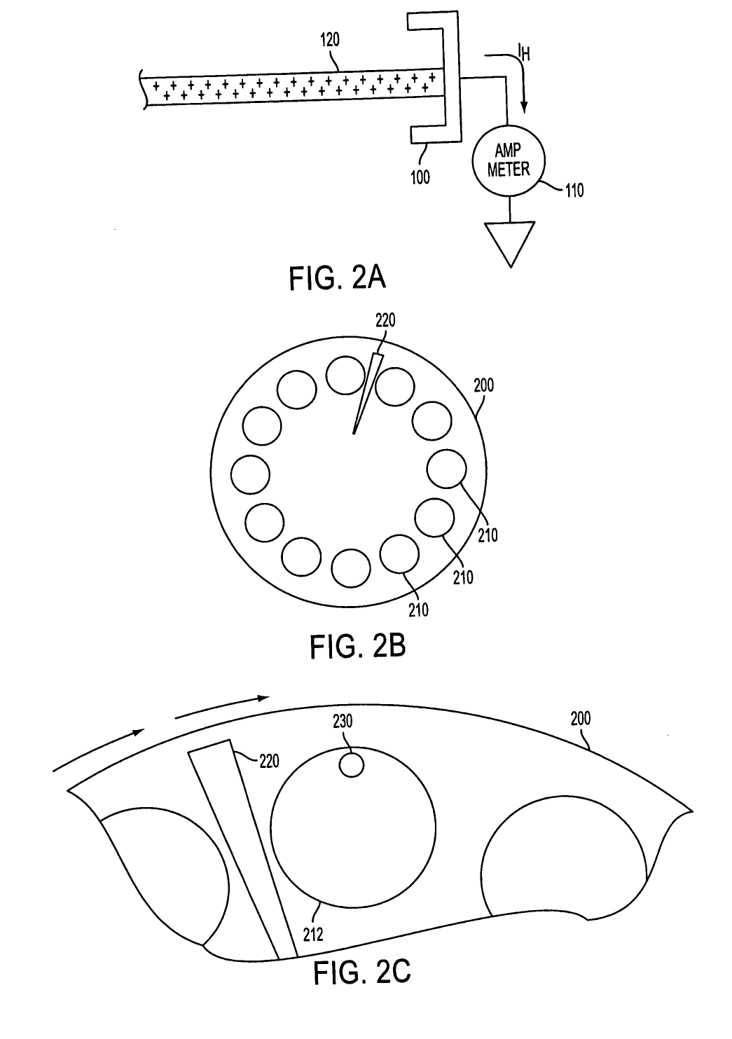

FIG. 2A is a schematic side view of a disk faraday used to determine beam current, which is in turn used to count the number of implanted ions. FIG. 2B is a top view of a disk holding a plurality of wafers for implantation. In FIG. 2B, a plurality of wafers 210 are arranged on the disk 200. A disk slot 220 is positioned among the wafers 210. An ion gun focuses a beam spot at one point on the wafers 210 as the disk 200 rotates.

FIG. 2C is an enlarged top view of the disk shown in FIG. 2B. In FIG. 2C, reference numeral 230 represents a beam spot, where the beam is currently being focused. If the disk 200 is being rotated in a clockwise direction with the beam spot 230 focused as shown, the beam spot 230 will move from wafer to wafer, implanting impurities toward the top of each wafer 210. According to one embodiment, the disk rotates at approximately 1200 rpm. As the disk rotates, a portion of the beam will extend through the disk via the disk slot 220. At this point, the beam spot 230 is directed through the disk 200 to the disk faraday 100 shown in FIG. 2A. The beam 120 contains ions. The disk faraday 100 is grounded. Electrons flow into the disk faraday 100 through a current meter 110 to thereby neutralize each of the ions. The current meter 110 counts the number of electrons, producing a current reading.

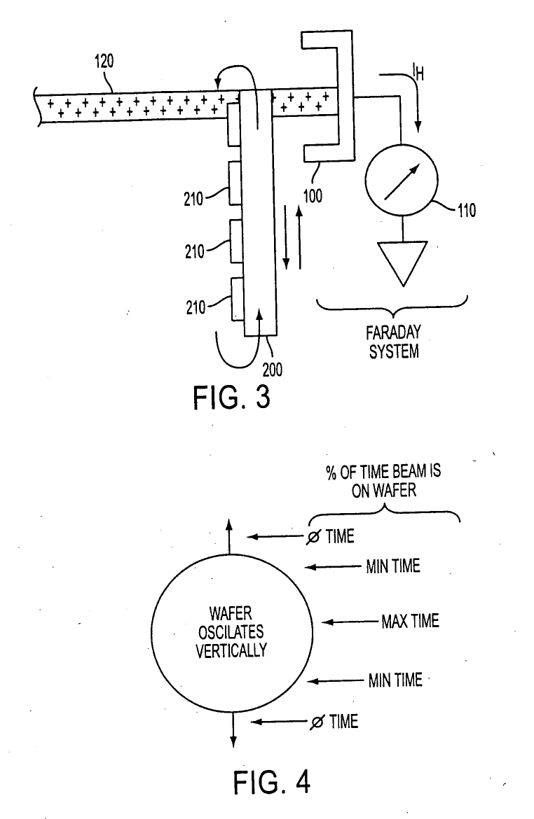

FIG. 3 is a side view of the disk faraday 100 shown in FIG. 2A and the disk 200 shown in FIGS. 2B and 2C. The disk 200 moves vertically up and down with respect to a horizontally traveling beam 120. This ensures that the beam 120 strikes the complete area of each wafer 210 mounted on the disk. Referring to FIG. 2C, the vertical travel path of the beam is such that the beam travels slightly past the top of the wafer 212 (where it is shown in FIG. 2C). When the beam is slightly above wafer 212, the beam changes direction to travel toward the bottom of the wafer 212. After traveling slightly paste the bottom of the wafer 212, the beam again changes direction so as to head toward the top of the wafer 212. The beam therefore stops and changes directions when the beam is not on the wafer.

The amount of outgassing is proportional to the amount of time that the beam is on the resist, which can be translated to the time the beam spends on the wafer. The beam spends time on the wafer, on the disk slot and the on the disk between, above and below the wafers.

FIG. 4 is a schematic representation of the time spent on the wafers during the beam travel path. When the beam is above or below the wafer, there is no time spent on the wafers. All of the time during the disk rotation is spent on the disk or possibly on the disk slot. When the beam is at the top and bottom of the wafer, there is a minimum time spent on the wafer. During each revolution of the disk 200, the beam 220 spends most of its time on the disk 200, rather than on a wafer 210. At the middle of the wafer, the beam spends the maximum time on the wafer.

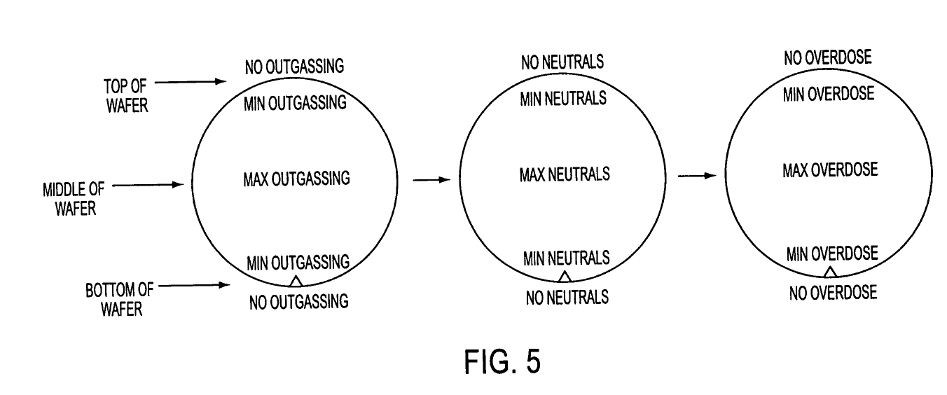

FIG. 5 shows the correlation between the time the beam spends on the wafer at various disk positions (FIG. 4), the amount of outgassing, the number of neutral species implanted and the amount of overdose if the neutral species are ignored in the calculations. When the beam is at the center of the wafer, there is more outgassing and beam neutralization. The current meter 110 detects fewer implanted ions. Without accounting for the neutralized atoms, the disk moves more slowly when the beam is focused at the center of the wafer. This allows the beam to implant more ions on the center of the wafer. Because the implanted neutralized atoms are ignored, this results an overdose in the center of the wafer.

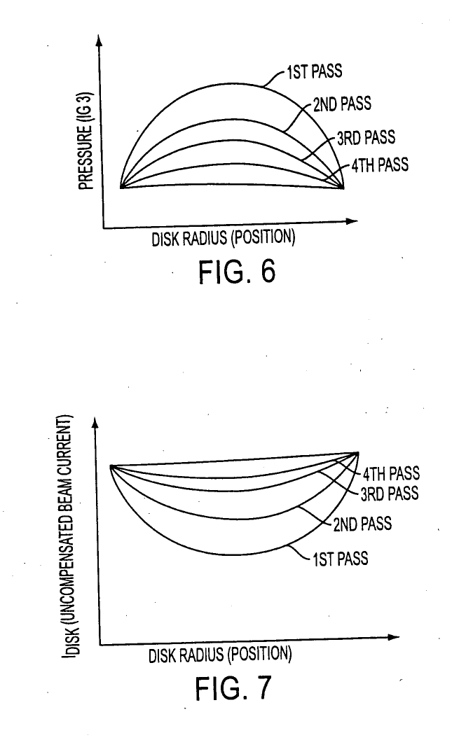

At the beginning of the implantation process, there is more resist to be burnt. There is therefore more resist outgassing at the beginning of the implantation process than at the end of the implantation process. Pressure is proportional to the amount of outgassing. FIG. 6 is an X-Y plot of outgassing as a function of disk radius. As can be seen, the largest pressure increase happens on the first pass of the ion beam over the wafer. There is less of a pressure increase with each succeeding pass. For each pass, the pressure increase is greatest at the center of the wafer. It should be noted that the beam may be traveling in opposite directions for each succeeding pass. For example, the first pass may be a downward pass, the second pass may be an upward pass, the third pass may be a downward pass, and so on. The outgassing is reduced with the each pass due to the decreasing availability of hydrogen and resist solvents in the organic resist. This is known as resist conditioning. FIG. 7 shows an X-Y plot of the uncompensated beam current I_{DISK} as a function of disk radius. FIG. 7 represents the current detected by the disk faraway. Comparing FIGS. 6 and 7, it can be seen that when there is maximum outgassing, the disk faraday detects the minimum current. This is because the outgassing causes the ions to recombine before implantation.

The dose system controls the vertical disk speed. It attempts to minimize vertical dose non-uniformity by changing the vertical disk speed in response to changes in the measured beam current I_{DISK} A drop in measured beam current causes the vertical disk speed to decrease at that vertical position so that an underdosing situation does not occur. The vertical disk speed may be varied while maintaining the same disk rotational speed. If the beam current drop is “legitimate” meaning it is caused by something that effects the number of implanted impurities (ions plus atoms), then dose uniformity is optimized by the vertical speed reduction. If the beam current drops due to beam neutralization, then overdosing occurs at the vertical position on the wafer that is being hit by the beam when the speed reduction occurs. Pressure changes are considered in order to differentiate between legitimate current drops and neutralization current drops. With the following equation, I_{DISK} to control vertical disk speed:
I_{DISK}=I_{DOSE}·e^{-KP}

For one revolution of the disk, the relative area struck by the beam spot is related to the circumference. That is, the closer the beam is to the center of the disk (not center of the wafer), the less area (wafers plus exposed disk) that is covered by the beam spot during each revolution. As the beam spot gets further towards the outer periphery of the disk, more area (wafers plus exposed disk) is covered during each revolution.

Since the area changes for a given disk position and the disk rotational speed does not change, the horizontal speed of the beam over the outer areas disk is greater. Toward the outer portions of the disk, fewer impurities are implanted per area for each rotation. To compensate for this and to ensure dose uniformity, the vertical speed of the disk changes.

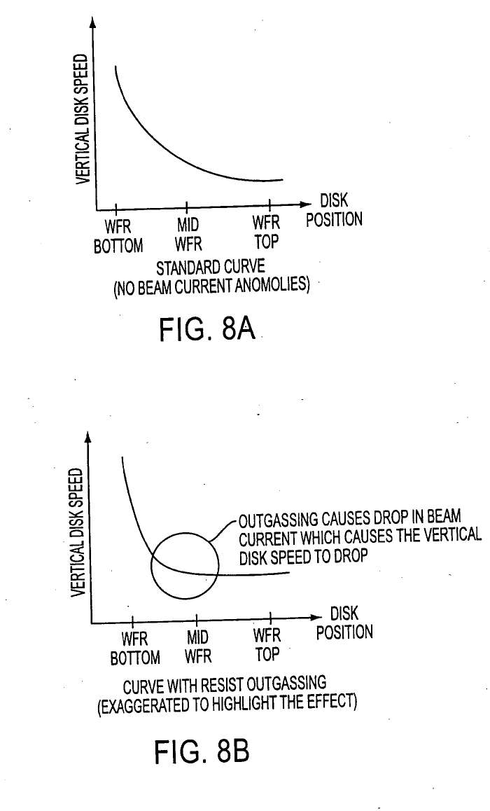

FIG. 8A is a plot of vertical disk speed versus disk position. The vertical speed is slowest towards the top of the wafer, where the horizontal disk speed is greatest. A slower vertical disk speed effectively allows the beam to implant on a given area for more revolutions the disk.

FIG. 8B is a plot of vertical disk speed versus disk position when outgassing causes a drop in beam current. The flat portion of the curve shown in FIG. 8B demonstrates that when there is outgassing toward the middle of the wafer, the vertical disk speed is slower than would otherwise be necessary.

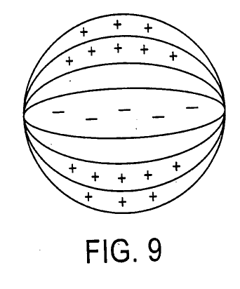

FIG. 9 is a sheet resistance map for a non-uniformly dosed wafer. Towards the middle of the wafer, the sheet resistance is less than the average sheet resistance. This indicates that there is overdosing toward the middle of the wafer. The sheet resistance of FIG. 4 can be obtained through testing, by placing probes at different positions on the wafer.

Some implanters minimize dose non-uniformity by ignoring beam current fluctuations. This can be done, for example, by not monitoring the beam current during “beam-on-wafer” time periods. That is, a disk faraday is not used during implanting. However, if there is a problem upstream from the wafer during implanting, which cases fewer impurities to enter the wafer, then this problem cannot be recognized. Alternatively, non-uniformity can be minimized by increasing the capacity of the cryo pumps. With more powerful pumps, the resist outgassing electrons are sucked into the cryo pumps as they are released. The inventors, however, are avoiding non-uniformities with pressure compensation and the formula below.
I_{MEASURED}=I_{DOSE}·e^{-KP}
I_{MEASURED} is also referred as I_{DISK}, and is current detected by the disk faraday. I_{DOSE} is the corrected dose current. The K-factor, which is input by the operator, either magnifies or diminishes the effect of pressure on the corrected dose current I_{DOSE}. If K is large, then an inaccuracy in I_{MEASURED} produces a large inaccuracy in the compensated beam current I_{DOSE}. While K should be high enough to assure cross wafer dose uniformity, a small K is better in terms of dealing with noise from the pressure sensor and avoiding inaccuracies.

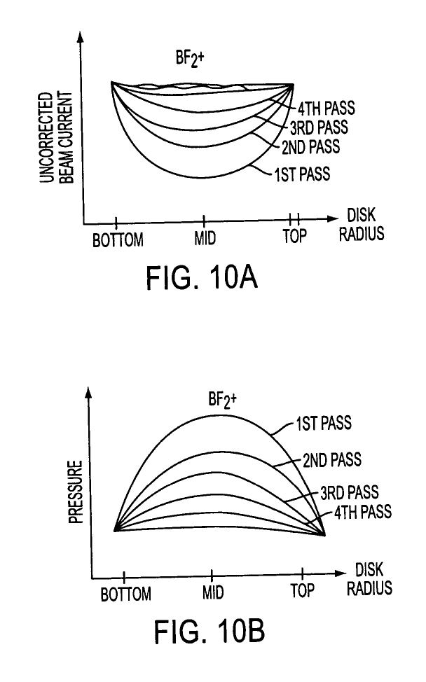

FIGS. 10A and 10B are plots of beam current and pressure versus disk position for a higher energy implant. The pressure readings for FIG. 10B were produced by an ion gauge at the conventional position. In FIG. 10A, the uncorrected beam current is plotted versus disk position. The uncorrected beam current is the current that is detected through the disk faraday. The bottom curve in FIG. 10A shows that for the first pass across the wafer, there is the greatest drop in beam current. This can be explained by reviewing FIG. 10B which shows that the pressure increase is greatest on the first pass over the wafer. On the first pass, there is maximum resist outgassing, which causes the pressure increase and introduces free electrons into the chamber in the vicinity of the wafer. The electrons cause ion beam neutralization and hence a drop in the detected current. Because of the significant pressure response detected, a smaller P-COMP value is sufficient to compensate for beam neutralization.

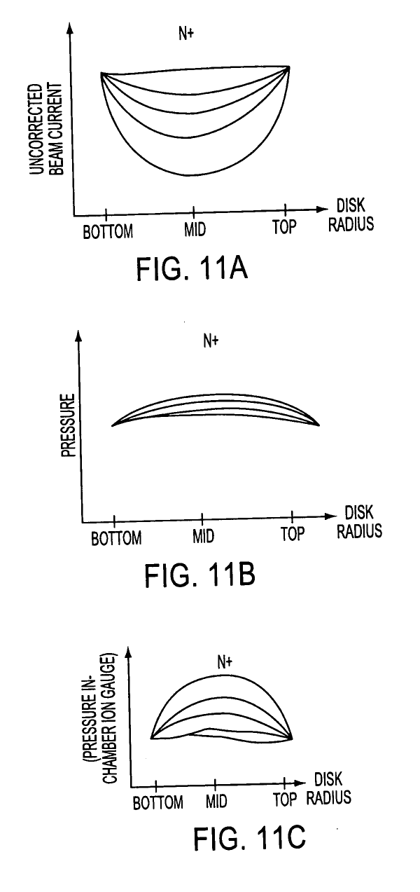

FIGS. 11A and 11B are plots of uncorrected beam current and pressure versus disk position for a lower power implant such as nitrogen. Again, the beam current is the beam current detected by a disk faraday. Like FIG. 10B, the pressure readings for FIG. 11B were produced by an ion gauge at the conventional position. As can be seen, significant beam neutralization (current drop) only produces small changes in the pressure reading. A very high P-COMP value is necessary in order to flatten out the beam current (I_{DOSE}) versus disk position curve.

The reason for this phenomenon is not yet fully understood. It could be that, under similar process conditions other than impurity species, low energy implants, such as N⁺, are much more likely to accept an electron (neutralization) than BF₂⁺, P⁺, or AS⁺. This would result in excessive/greater beam current drop, as a function of pressure. Conditional P-COMP systems and ion gauges, while being very accurate for other (high energy) implant processes, are not sufficient for N⁺. One solution to this problem is to increase the ion gauge response in order to bring it up to the magnitude with which the implanter works. In order to achieve this, pressure must be monitored close to where the resist outgassing occurs. Conventional ion gauges resides upstream of the beam gate, outside of the process chamber, next to the cryo pump. This location is too far from the outgassing source (and too close to the cryo) to detect more subtle pressure fluctuations. Placing the pressure monitor in the process chamber results in the pressure response shown in FIG. 11C, which is another plot of pressure versus disk radius. Unlike FIGS. 10B and 11B, the pressure readings for FIG. 11C were produced by an ion gauge located within the process chamber. Comparing FIG. 11C with FIG. 11B, it can be seen that if the ion gauge is located within the process chamber for low energy implants, a sufficient pressure response is produced.

Placing an ion gauge in the process chamber results in much smaller P-COMP values than an ion gauge placed at the conventional location. For example, a P-COMP of 7 is possible instead of a P-COMP in excess of 150. This is a dramatic improvement as it drastically reduces dose inaccuracies/functuations and increases dose repeatability by reducing the affect of ion gauge inaccuracies.

Placing an ion gauge in the process chamber, while desirable for low energy impurities, such as N⁺, makes the pressure readings unacceptable for the other processes such as high energy implants. Therefore, the ion gauge within the process chamber does not replace the ion gauge located downstream, toward a cryo pump. Both ion gauges should be installed. Depending on the process/recipe, the operator should switch between the ion gauges.

An alternate solution is to place two ion gauges within the process chamber. The first ion gauges should be a highly sensitive ion gauge, which accurately detects pressures below a given threshold, perhaps 1×10⁻⁴ Torr. A second ion gauge is positioned within the process chamber, perhaps at the same general location as the first pressure gauge. The second ion gauge is less sensitive than the first ion gauge. For example, the second ion gauge can detect pressures above the given threshold, perhaps 1×10⁻⁴ Torr. The first ion gauge is used for low energy implants, and the second ion gauge is used for high energy implants.

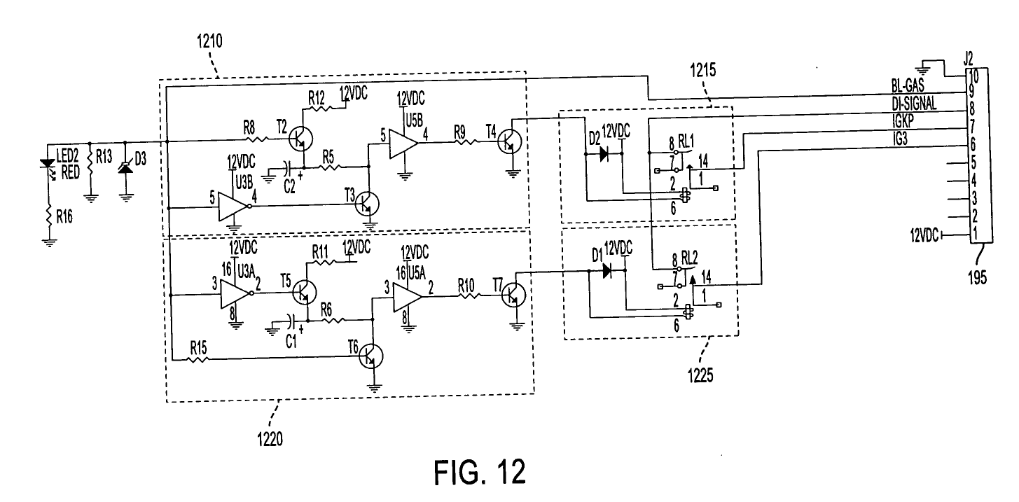

FIG. 12 is a schematic view of a switching circuit to switch between the first and second ion gauge (pressure sensors) shown in FIG. 1A. FIG. 12 shows the connector 195 of the pressure sensor controller 155 shown in FIGS. 1 and 2. Pin number 9 is a beam line gas signal. Beam line gas is a parameter that serves to focus the beam on the wafer. The beam line gas is a parameter that may not be used for either high energy implants, such as BF₂⁺, P⁺, As⁺, and low energy implants such as nitrogen. Although beam line gas is shown in FIG. 12, any recipe parameter that is unused for both high and low energy implants could be used for the circuit shown in FIG. 12. The beam line gas is part of the recipe, which may be developed through the user interface shown in FIG. 1A. Because beam line gas is not used for either high or low energy implants, the recipes would normally call for beam line gas to be off. However, the inventors propose using the beam line gas parameter to select an ion gauge. Thus, the beam line gas recipe parameter now serves an important function.

Pin number 8 is a digital interface signal. The digital interface signal is low when one of the pressure sensors is to be on and high when both of the pressure sensors are to be off. Pin number 7 is the controller input for pressure sensor 2. Pin number 6 is the controller input for pressure sensor 1. If only one of the two pressure sensors (ion gauges) were to be used, the digital interface signal could simply be jumped from pin number 8 to either pin number 7 or pin number 6.

The circuit shown in FIG. 12 allows the user to select between either the first or second pressure sensor and allows the operator to select the appropriate pressure sensor automatically. The circuit shown in FIG. 12 has two delay circuits and two relays. Delay circuit 1210 is connected to relay circuit 1215, and delay circuit 1220 is connected to relay circuit 1225. Both of the delay circuits 1210 and 1220 have two inputs, for a total of four inputs. Each of these four inputs is connected to the beam line gas signal. The delay circuits 1210 and 1220 are substantially the same. However, inverters U3A and U3B cause the delay circuits to operate at different times. Transistor T2 is similar to transistor T5. However, transistor T2 is connected to a resistor R8, and transistor T5 is connected to an inverter U3A. Transistor T3 is similar to transistor T6. However, transistor T3 is connected to an inverter U3B, and transistor T6 is connected to a resistor R15. With these connections, transistor T2 is on when transistor T5 is off. Transistor T3 is off when transistor T6 is on. Because of the similarities between the two delay circuits 1210, 1220, only one will be described in detail.

Transistor T2 through the capacitor C2 and resistor R5 form a delay circuit together with the associated components. The RC time constant of C2 and R5 determines how long transistor T2 must be on before a signal is received at U5B. U5B together with R9 and T4 assure that an accurate voltage signal is output even if the input to U5B fluctuates. They also serve to control the timing of the delay circuit such that the delay does not change with changing temperature, for example.

When transistor T2 is on and a signal is eventually output through U5B, and R9 and T4, the second pressure sensor is turned on through pin 7 of the ion gauge controller. When transistor T2 is on, transistor T3 is off. Thus, transistor T3 has no effect when the delay circuit is working to activate the second pressure sensor. However, when transistor T2 is off, transistor T3 is on. The purpose of transistor T3 is to discharge the capacitor C2. In this manner, when transistor T2 is again turned on, the RC time constant will not be altered by any charge stored from a previous operation.

The delay circuit 1220 operates substantially the same as the delay circuit 1210 with the exception that the components U5A, R10 and T7 produce an on signal when the components U5B, R9 and T4 produce an off signal.

The delay circuits 1210 and 1220 are connected to the pressure sensor controller through respective relay circuits 1215 and 1225. Both relay circuits 1215 and 1225 receive the digital input signal from pin 8. When the relay circuit 1215 or 1225 receives a high signal from the delay circuit 1210 or 1220, the relay circuit 1215 or 1225 effectively passes the digital input signal from pin 8 to pin 7 or 6. The relay circuits 1215 and 1225 are used instead of a direct connection in order to provide insulation from the rest of the device. In some applications, it is certainly possible to eliminate the relay circuits 1215 and 1225.

The devices labeled U5A and U5B together form a hex buffer between each delay circuit and the associated relay circuits. The hex buffer is a logic device which outputs a predetermined voltage when an input voltage is greater than or equal to a certain voltage. For example, referring to hex buffer U5A, when pin 3 reaches a voltage greater than or equal to five volts, a five-voltage signal will be output on pin 2.

FIG. 12 shows an indicator light LED2. This indicator light can be used to inform the operator which pressure sensor is operating. Alternatively, this can be done through the user interface shown in FIG. 1A. Although the pressure gauge controller has inputs for two ion gauges, it is not designed to switch between the two ion gauges. Thus, an instantaneous digital switching signal is ineffective. With the circuit shown in FIG. 12, sufficient delay is provided. The delay emulates an operator mechanically changing a jumper between pins 6 and 7. This jumper would connect one of pins 6 and 7 to pin 8.

When the pressure sensor/ion gauge controller is instructed to operate either the first or second pressure sensor, the pressure sensor controller communicates with the appropriate pressure sensor through the connector 175 or the connector 185 (see FIG. 1B), as described previously.

The invention has been described in detail with particular reference to preferred embodiments thereof and examples, but it will be understood that variations and modifications can be effected within the spirit and scope of the invention.

1. A device to implant impurities into a semiconductor wafer, comprising:
a beam gun to shoot ions at a semiconductor wafer;
a pair of ion gauges;
an ion gauge controller to supply power to, and obtain information corresponding to a number of ions from, one of the ion gauges, the ion gauge controller comprising:
a pair of control inputs respectively associated with the pair of ion gauges, such that when a control signal is supplied to one of the control inputs, the ion gauge controller supplies power to, and obtains information corresponding to a number of ions from, the respectively associated ion gauge;
a control output to produce the control signal when either of the ion gauges is activated; and
a parameter output to selectively produce a parameter signal based on a recipe selection;
a first delay circuit to connect the control output to one of the control inputs, after a delay, when the parameter output is on; and
a second delay circuit to connect the control output to the other of the control inputs, after a delay, when the parameter output is off.

2. A device to implant impurities according to claim 1, wherein the control output is a beam line gas output.

3. A device to implant impurities according to claim 2, wherein the beam line gas output is connected to a beam line gas device, which is capped.

4. A device to implant impurities according to claim 1, further comprising a pair of relay circuits each connected between one of the delay circuits and one of the control inputs to connect the control output to one of the control inputs when a voltage signal is received from the delay circuit connected thereto.

5. A device to implant impurities according to claim 4, further comprising a hex buffer connected between each delay circuit and the corresponding relay circuit.

6. A device to implant impurities according to claim 1, wherein
an inverter is positioned between the parameter output and one of the delay circuits such that one of the delay circuits is turned on when the other delay circuit is turned off, and
each delay circuit comprises:
a resistor-capacitor combination to produce a constant time delay when the delay circuit is turned on; and
a discharge transistor to discharge the resistor-capacitor combination when the delay circuit is turned off.

7. A device to implant impurities according to claim 1, wherein
the first delay circuit comprises:
a first charging transistor connected to the parameter output;
a first resistor-capacitor combination to produce a constant time delay when the first charging transistor is turned on;
a first discharging transistor to discharge the capacitor of the first resistor-capacitor combination when the first charging transistor is turned off; and
a first inverter connected between the parameter output and the first discharging transistor, and
the second delay circuit comprises:
a second charging transistor;
a second inverter connected between the parameter output and the second charging transistor;
a second resistor-capacitor combination to produce a constant time delay when the charging transistor is turned on; and
a second discharge transistor connected to the parameter output to discharge the capacitor of the second capacitor-resistor combination when the second charging transistor is turned off.

8. A device to implant impurities into a semiconductor wafer according to claim 1, wherein the device is an Axelis GSD platform implanter.

9. A device to implant impurities into a semiconductor wafer according to claim 1, wherein the first ion gauge is used for high resist outgassing implants and the second ion gauge is used for low resist outgassing implants.

10. A device to implant impurities into a semiconductor wafer, comprising:
a base unit having a plurality of interfaces comprising an input to receive an implant recipe an unused output to control a recipe parameter not used in both a high resist outgassing implant and a low resist outgassing implant;
an ion gauge controller provided in the base unit;
a beam gun to shoot ions at a semiconductor wafer;
first and second ion gauges; and
a switch to selectively connect either the first or second ion gauge to the ion gauge controller, the switch being activated by a trigger connected to the unused interface of the base unit.

11. A method for a pair of ion gauges in a semiconductor wafer implantation device, the ion gauges being controlled through an ion gauge controller, the method comprising:
connecting a first delay circuit to a first control input on the ion gauge controller, the first control input activating one of the ion gauges when an on signal is supplied thereto;
connecting a second delay circuit to a second control input on the ion gauge controller, the second control input activating the other of the ion gauges when an on signal is supplied thereto;
connecting the first and second delay circuits to a parameter output which produces a parameter signal based on a recipe selection;
positioning an inverter between one of the delay circuits and the parameter output; and
connecting a control output to each of the delay circuits such that the control output is switched between one of the control inputs, with a delay, depending on whether the parameter output is on or off.

12. A method for a pair of ion gauges in a semiconductor wafer implantation device according to claim 11, further comprising:
removing the first and second delay circuits; and
connecting a jumper between the control output and one of the control inputs.
